(19) United States
(12) Patent Application Publication
(10) Pub. No.: US 2008/0286920 A1
(43) Pub. Date: Nov. 20, 2008

(54) METHOD FOR MANUFACTURING SEMICONDUCTOR DEVICE

(76) Inventor: Jea Hee KIM, Yeoju-gun (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/122,495

(22) Filed: May 16, 2008

(30) Foreign Application Priority Data
May 17, 2007 (KR) 10-2007-0047986

(51) Int. Cl. H01L 21/8238; H01L 21/8234

(52) U.S. Cl. 438/218; 438/294; 257/E21.63; 257/E21.632

(57) ABSTRACT

A method for manufacturing a semiconductor device is provided. The method includes forming a negative photoresist layer on a semiconductor substrate, forming a photoresist pattern on the negative photoresist layer, forming a well region in the semiconductor substrate, implanting ions into the semiconductor substrate, using the photoresist pattern as a mask, such that the ions are implanted into the well region, removing the photoresist pattern, and forming a gate region and a source/drain region on the semiconductor substrate.

### RELATED APPLICATION

The present application claims the benefit of priority under 35 U.S.C. 119 to Korean Patent Application No. 10-2007-0047986, filed on May 17, 2007, the entire contents of which are incorporated herein by reference.

### BACKGROUND

Embodiments consistent with the present invention relate to a method for manufacturing a semiconductor device.

As semiconductor devices become more highly integrated, a length of a gate electrode has been scaled down to a micro-size, so that a short channel effect increasingly occurs in the semiconductor devices. Such a short channel effect is mainly caused by the reduction of the effective channel length of the gate electrode due to the lateral diffusion of a source/drain diffusion layer into a channel region.

In addition, after an ion implantation process has been performed to form a well region in a metal-oxide-semiconductor (MOS) device, dopants are often concentrated on a surface of the well region. As a result, a punch-through phenomenon often occurs in the MOS device, thereby degrading the operational characteristics of the MOS device.

In order to reduce the short channel effect, the effective channel length must be increased by restricting the lateral diffusion of the diffusion layer. One way to restrict the lateral diffusion is to reduce the depth of the source/drain diffusion layer.

### SUMMARY

Embodiments consistent with the present invention may provide a method for manufacturing a semiconductor device. The method may be capable of forming a shallow junction in the semiconductor device by shallowly implanting ions for adjusting a threshold voltage in a well region.

In an embodiment consistent with the present invention, the method includes forming a negative photoresist layer on a semiconductor substrate, forming a photoresist pattern on the negative photoresist layer, forming a well region in the semiconductor substrate, implanting ions into the semiconductor substrate, using the photoresist pattern as a mask, such that the ions are implanted into the well region, removing the photoresist pattern, and forming a gate region and a source/drain region on the semiconductor substrate.

In another embodiment consistent with the present invention, the method includes forming a first negative photoresist layer on a semiconductor substrate, the semiconductor substrate having a first region and a second region, forming a first positive photoresist pattern on a portion of the first negative photoresist covering the second region, forming an N well region in the first region of the semiconductor substrate, performing a first ion implantation process on the N well region, removing the first negative photoresist and the first positive photoresist pattern, forming a second negative photoresist on the semiconductor substrate, forming a second positive photoresist pattern on a portion of the second negative photoresist covering the first region, forming a P well region in the second region of the semiconductor substrate, performing a second ion implantation process on the P well, removing the second negative photoresist and the second positive photoresist pattern, and forming a gate region and a source/drain region on the first and second regions of the semiconductor substrate.

### BRIEF DESCRIPTION OF THE DRAWINGS

FIGS. 1 to 9 are sectional views illustrating a method for manufacturing a semiconductor device according to embodiments consistent with the present invention.

### DETAILED DESCRIPTION

Hereinafter, embodiments consistent with the present invention will be described in detail with reference to accompanying drawings. In the following detailed description, it is to be understood that, when a layer is referred to as being “on” or “over” another layer, the layer may be directly on the other layer, or intervening layers may be present between the layers. The thickness and size of each layer shown in the drawings may be exaggerated, omitted, or schematically drawn for the purpose of convenience or clarity. In addition, the size of elements shown in the drawings does not utterly reflect an actual size.

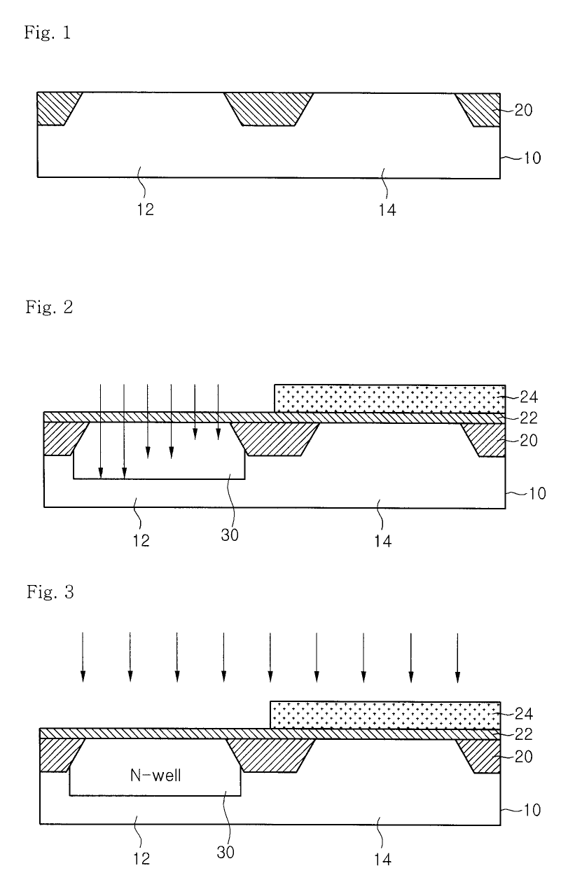

FIGS. 1 to 9 illustrates a method for manufacturing a semiconductor device according to embodiments consistent with the present invention.

Referring to FIG. 1, a field oxide layer 20 is formed on a semiconductor substrate 10 by performing a shallow trench isolation (STI) process. Consistent with the present invention, other suitable processes, such as a local oxidation of silicon (LOCOS) process may also be performed. Field oxide layer 20 may define a plurality of active regions on semiconductor substrate 10. For example, as shown in FIG. 1, field oxide layer 20 defines a first active region 12 and a second active region 14 on semiconductor substrate 10. It is to be understood that more active regions can be defined by field oxide layer 20.

Referring to FIG. 2, a first negative photoresist layer 22 is formed on semiconductor substrate 10 and a first positive photoresist pattern 24 is formed on first negative photoresist layer 22. In one embodiment, first negative photoresist layer 22 may have a thickness of about 100 Å to about 1,000 Å, and first positive photoresist pattern 24 may be formed by exposing and developing a first photoresist layer (not shown), so as to cover second active region 14 and leaving first active region 12 exposed.

Referring again to FIG. 2, an N well region 30 is formed by performing a first ion implantation process having three steps, in which ion implantation energy and the dosage of implanted dopants may be adjusted. In one embodiment, in the first step of the first ion implantation process, phosphorus ions (e.g., ³¹P) may be used as a source. Further, the ion implantation energy may be about 400 keV to about 1000 keV and the dosage of the implanted dopants may be about 1×10¹³ [atoms/cm²] to about 2×10¹³ [atoms/cm²]. In addition, in the second step of the first ion implantation process, phosphorus ions (e.g., ³¹P) may also be used as a source, the ion implantation energy may be about 100 keV to about 300 keV, and the dosage of the implanted dopants may be about 1×10¹³ [atoms/cm²] to about 2×10¹³. In the third step of the first ion implantation process, arsenic ions (e.g., ⁷⁵As) may be used as a source, the ion implantation energy may be about 50 keV to about 200 keV, and the dosage of the implanted dopants may be about 1×10¹¹ [atoms/cm²] to about 1×10¹³ [atoms/cm²]. Although specific ion sources have be described, it is appreciated that any ions of the pnictogens (or group V elements) may be used as a source in the first ion implantation process.

In one embodiment, N well region 30 formed through the first ion implantation process may have a retrograde well structure. Accordingly, N well region 30 may have a uniform concentration over the entire region thereof. Accordingly, ions for forming N well region 30 may be prevented from being concentrated at an upper portion of N well region 30, thereby preventing a punch-through phenomenon.

Referring to FIG. 3, a second ion implantation process for adjusting a threshold voltage is performed on semiconductor substrate 10. In one embodiment, the second ion implantation process may be performed using boron ions (e.g., ¹¹B) as a source with an implantation energy of about 10 keV to about 80 keV and an implantation dosage of about 1.0×10¹² [atoms/cm²] to 1.0×10¹³ [atoms/cm²]. It is appreciated that any ions of the earth metals (or group III elements) may be used as a source in the second ion implantation process. In one embodiment, the second first ion implantation process may include a blanket ion implantation process. Due to the existence of first negative photoresist layer 22, the ions for adjusting the threshold voltage is shallowly formed in N well region 30. As a result, when a heat treatment process is performed after the formation of a source/drain junction, the junction is prevented from diffusing due to transient enhanced diffusion (TED), thereby realizing a shallow junction. Then, an ashing process may be performed to remove first positive photoresist pattern 24 and first negative photoresist layer 22.

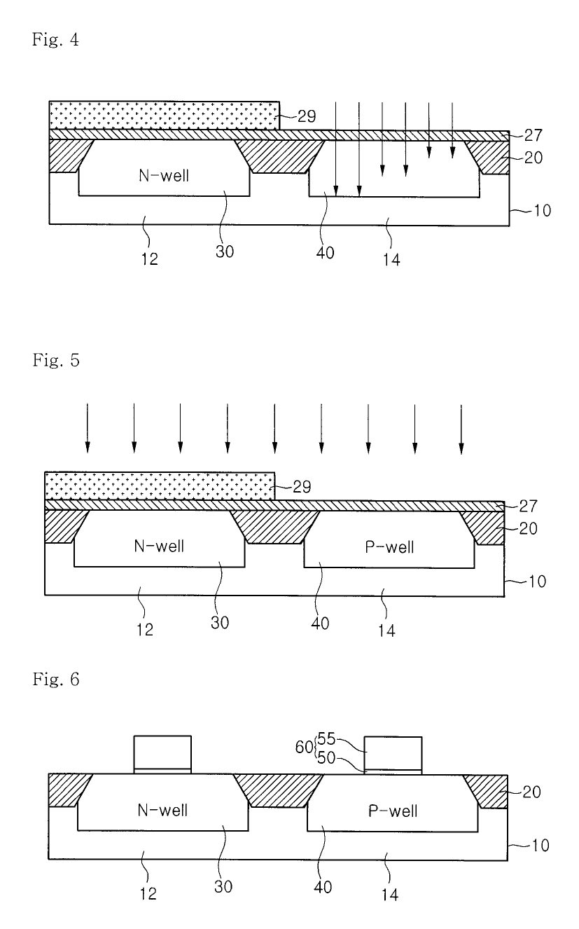

Referring to FIG. 4, a second negative photoresist layer 27 and a second photoresist pattern 29 are formed on semiconductor substrate 10, on which N well region 30 has been formed. Second positive photoresist pattern 29 may be formed by exposing and developing a second positive photoresist layer (not shown), so as to cover first active region 12, leaving second active region 14 exposed. Then, a third ion implantation process, which has a three step process similar to the first ion implantation process, may be performed to form a P well region 40. In the third ion implantation process, ion implantation energy and the implantation dosage of implanted dopants may be adjusted.

In one embodiment, in the first step of the third ion implantation process, boron ions (e.g., ¹¹B) may be used as a source with an ion implantation energy of about 250˜500 keV and an implantation dosage of about 1×10¹³ [atoms/cm²] to 4×10¹³ [atoms/cm²]. In addition, in the second step of the third ion implantation process, boron ions (e.g., ¹¹B) may be used as a source with an ion implantation energy of about 70˜200 keV and an implantation dosage of about 1×10¹³ [atoms/cm²] to about 3×10¹³ [atoms/cm²]. In the third step of the third ion implantation process, boron ions (e.g., ¹¹B) may be used as a source with an ion implantation energy of about 10˜50 keV and an implantation dosage of about 1×10¹² [atoms/cm²] to about 3×10¹² [atoms/cm²]. It is appreciated that any ions of the earth metals (or group III elements) may be used as a source in the third ion implantation process. Accordingly, a P well region 40 having a retrograde well structure may be formed through the third ion implantation process, and P well region 40 may have a uniform concentration over the entire region thereof. Ions for forming P well region 40 may be prevented from being concentrated only near an upper portion of P well region 40, thereby preventing a punch-through phenomenon.

Referring to FIG. 5, a fourth ion implantation process, for adjusting a threshold voltage, is performed on semiconductor substrate 10. The fourth ion implantation process may be performed using arsenic ions (e.g., ⁷⁵As) as a source with an ion implantation energy of about 10 keV to 100 keV and an implantation dosage of about 3.0×10¹² [atoms/cm²] to about 1.0×10¹³ [atoms/cm²]. It is appreciated that any ions of the pnictogens (or group V elements) may be used as a source in the fourth ion implantation process. In one embodiment, the fourth ion implantation process may include a blanket ion implantation process. Due to the existence of second negative photoresist layer 27, the ions for adjusting the threshold voltage may be shallowly formed in P well region 40. As a result, when a heat treatment process is performed after the formation of the source/drain junction, the junction may be prevented from diffusing due to transient enhanced diffusion (TED), thereby realizing a shallow junction. Then, an ashing process may be performed to remove second positive photoresist pattern 29 and second negative photoresist layer 27. Further, N well region 30 and P well region 40 may be activated by using a furnace or a rapid thermal process (RTP).

Referring to FIG. 6, a gate 60 is formed on semiconductor substrate 10, on which N well region 30 and P well region 40 have been formed. Gate 60 includes an oxide layer pattern 50 and a polysilicon pattern 55, which are formed by patterning an oxide layer (not shown) and a polysilicon layer (not shown) formed on semiconductor substrate 10.

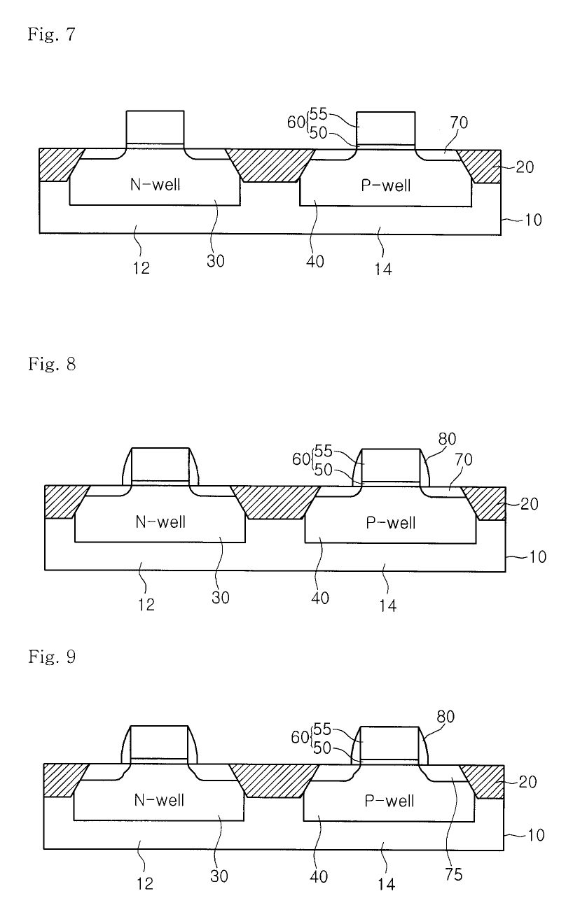

Referring to FIG. 7, lightly concentrated impurities (N type or P type impurity) may be implanted on semiconductor substrate 10 by using gate 60 as a mask, so that a lightly doped drain (LDD) region 70 is formed. Then, LDD region 70 may be activated by using a furnace or the RTP described above.

Referring to FIG. 8, a spacer 80 having an oxide-nitride-oxide (ONO) structure may be formed at both sides of gate 60. In one embodiment, spacer 80 may be formed by sequentially depositing oxide, nitride, and oxide on semiconductor substrate 10. Semiconductor substrate 10 may be subjected to an annealing process and an etching process, so as to form spacer 80 at both sides of gate 60. Although spacer 80 has been described to have an ONO structure, it is appreciated that spacer 80 may have other structures. For example, spacer 80 may have an oxide-nitride (ON) structure.

Referring to FIG. 9, a source/drain region 75 may be formed on the semiconductor substrate 10 by performing a fifth ion implantation process using spacer 80 and gate 60 as a mask. Then, a heat treatment process may be performed to activate dopants implanted into source/drain region 75. Since the ions are shallowly implanted in N well region 30 and P well region 40, the implanted ions are prevented from diffusing in a depth direction in source/drain region 75 during the heat treatment process, thereby realizing a shallow source/drain junction.

Although not shown in the drawings, an interlayer dielectric layer may be formed on semiconductor substrate 10 and may be selectively etched to form a via-hole, and then a contact plug may be formed in the via-hole. Gate 60 may be electrically connected to source/drain region 75 through the contact plug.

Any reference in this specification to “one embodiment,” “an embodiment,” “example embodiment,” etc., means that a particular feature, structure, or characteristic described in connection with the embodiment is included in at least one embodiment consistent with the present invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments consistent with the present invention have been described with reference to a number of illustrative embodiments thereof, it should be understood that numerous other embodiments can be devised by those skilled in the art that will fall within the spirit and scope of the appended claims. More particularly, various variations and modifications are possible in the component parts and/or arrangements of the subject combination arrangement within the scope of the appended claims. In addition to variations and modifications in the component parts and/or arrangements, alternative uses will also be apparent to those skilled in the art.

What is claimed is:

1. A method for manufacturing a semiconductor device, the method comprising:
forming a negative photoresist layer on a semiconductor substrate;
forming a photoresist pattern on the negative photoresist layer;
forming a well region in the semiconductor substrate;
implanting ions into the semiconductor substrate, using the photoresist pattern as a mask, such that the ions are implanted into the well region;
removing the photoresist pattern; and
forming a gate region and a source/drain region on the semiconductor substrate.

2. The method as claimed in claim 1, wherein forming the well region comprises forming an N well region by performing an ion implantation process using boron ions as an ion source.

3. The method as claimed in claim 1, wherein forming the well region comprises forming a P well region by performing an ion implantation process using arsenic ions as an ion source.

4. The method as claimed in claim 1, wherein forming the photoresist pattern includes forming the photoresist pattern to have a thickness of about 100 Å to about 1000 Å.

5. The method as claimed in claim 1, wherein the well region has a retrograde well structure.

6. The method as claimed in claim 1, wherein forming the well region comprises performing a three-step ion implantation process.

7. A method for manufacturing a semiconductor device, the method comprising:
forming a first negative photoresist layer on a semiconductor substrate, the semiconductor substrate having a first region and a second region;
forming a first positive photoresist pattern on a portion of the first negative photoresist covering the second region;
forming an N well region in the first region of the semiconductor substrate;
performing a first ion implantation process on the N well region;
removing the first negative photoresist and the first positive photoresist pattern;
forming a second negative photoresist on the semiconductor substrate;
forming a second positive photoresist pattern on a portion of the second negative photoresist covering the first region;
forming a P well region in the second region of the semiconductor substrate;
performing a second ion implantation process on the P well;
removing the second negative photoresist and the second positive photoresist pattern; and
forming a gate region and a source/drain region on the first and second regions of the semiconductor substrate.

8. The method as claimed in claim 7, wherein the first negative photoresist and the second negative photoresist have a thickness of about 100 Å to about 1,000 Å.

9. The method as claimed in claim 7, wherein performing the first ion implantation process or performing the second ion implantation process comprises performing a blanket ion implantation process.

10. The method as claimed in claim 7, wherein the N well region and the P well region have a retrograde well structure.

11. The method as claimed in claim 7, wherein forming the N well region or forming the P well region comprises performing a three-step ion implantation process.

12. The method as claimed in claim 7, wherein performing the first ion implantation process comprises performing the first ion implantation process using boron ions as an ion source.

13. The method as claimed in claim 7, wherein performing the second ion implantation process comprises performing the second ion implantation process using arsenic ions as an ion source.
